(19) United States
(12) Patent Application Publication
(10) Pub. No.: US 2025/0226302 A1
(43) Pub. Date: Jul. 10, 2025

(54) HYBRID SUBSTRATE WITH EMBEDDED COMPONENT

(71) Applicant: QUALCOMM Incorporated, San Diego, CA (US)

(72) Inventors: Yeoil PARK, Sejong (KR); Hyunchul CHO, Suwon (KR); Jaehyun YEON, San Diego, CA (US); Suhyung HWANG, Rancho Mission Viejo, CA (US); Kun FANG, San Diego, CA (US)

(21) Appl. No.: 18/405,570

(22) Filed: Jan. 5, 2024

(51) Int. Cl. H01L 23/498; H01L 21/027; H01L 21/304; H01L 23/00; H01L 25/065

(52) U.S. Cl. CPC H01L 23/49838; H01L 21/0274; H01L 21/304; H01L 23/49822; H01L 24/13; H01L 24/29; H01L 25/0655; H01L 2224/13007; H01L 2224/13025; H01L 2224/29006; H01L 2224/29025; H01L 2924/01029; H01L 2924/1431; H01L 2924/1434; H01L 2924/182

(57) ABSTRACT

In an aspect, an apparatus includes a base substrate having a first side and a second side. A first substrate on the first side of the base substrate having a first embedded component disposed in a cavity adjacent the first side of the base substrate. A second substrate is on the second side of the base substrate. A first connection structure is disposed between the first substrate and the base substrate configured to electrically couple the first substrate to the base substrate. A second connection structure is disposed between the second substrate and the base substrate configured to electrically couple the second substrate to the base substrate.

### TECHNICAL FIELD

The present disclosure generally relates to semiconductor devices including an integrated circuit (IC) package, and more particularly, but not exclusively, to devices including a hybrid substrate with at least one embedded component and fabrication techniques thereof.

### BACKGROUND

IC technology has achieved great strides in advancing computing power through miniaturization of electronic components. An IC chip or an IC die may include a set of circuits integrated thereon. In some implementations, an IC device may be formed by incorporating and protecting one or more IC chips or dies in an IC package, where various power and signal nodes of the one or more IC chips can be electrically coupled to respective conductive terminals of the IC package via electrical paths formed in one or more package substrates of the IC package. The term “substrate” in this disclosure, unless otherwise specified, refers to a packaging substrate for packaging one or more IC chips into an IC package, which is different from the semiconductor substrate for forming an IC chip.

Various packaging technologies can be found in many electronic devices, including processors, servers, radio frequency (RF) ICs, etc. Advanced packaging and processing techniques allow for complex devices, such as multi-die devices and system on a chip (SOC) devices, which may include multiple function blocks, with each function block designed to perform a specific function, such as, for example, a microprocessor function, a graphics processing unit (GPU) function, a communications function (e.g., Wi-Fi, Bluetooth, and other communications), and the like. As used herein the term “function block” should not be construed to be power or signal lines, traces, conductors, pads, etc. that merely function to transmit an electrical voltage and/or current.

As designs become more complex, design restrictions for distances between dies and components become more difficult to maintain because of substrate structure. The more complex designs may include many stacked substrates and increased thicknesses of the IC package. To enhance design flexibility and reduce the distance between dies and components, controllable based on the substrate design.

Accordingly, there is a need for improved substrates for an IC package and methods of manufacturing the same to address the above-noted issues, as disclosed herein.

### SUMMARY

The following presents a simplified summary relating to one or more aspects disclosed herein. Thus, the following summary should not be considered an extensive overview relating to all contemplated aspects, nor should the following summary be considered to identify key or critical elements relating to all contemplated aspects or to delineate the scope associated with any particular aspect. Accordingly, the following summary has the sole purpose to present certain concepts relating to one or more aspects relating to the mechanisms disclosed herein in a simplified form to precede the detailed description presented below.

In an aspect, an apparatus includes a base substrate having a first side and a second side; a first substrate on the first side of the base substrate, the first substrate having a first embedded component disposed in a cavity adjacent the first side of the base substrate; a second substrate on the second side of the base substrate; a first connection structure disposed between the first substrate and the base substrate configured to electrically couple the first substrate to the base substrate; and a second connection structure disposed between the second substrate and the base substrate configured to electrically couple the second substrate to the base substrate.

In an aspect, a method of manufacturing an apparatus includes forming a base substrate having a first side and a second side; forming a first substrate on the first side of the base substrate, the first substrate having a first embedded component disposed in a cavity adjacent the first side of the base substrate; forming a second substrate on the second side of the base substrate; forming a first connection structure disposed between the first substrate and the base substrate configured to electrically couple the first substrate to the base substrate; and forming a second connection structure disposed between the second substrate and the base substrate configured to electrically couple the second substrate to the base substrate.

Other objects and advantages associated with the aspects disclosed herein will be apparent to those skilled in the art based on the accompanying drawings and detailed description.

### BRIEF DESCRIPTION OF THE DRAWINGS

The accompanying drawings are presented to aid in the description of various aspects of the disclosure and are provided solely for illustration of the aspects and not limitation thereof.

FIGS. 1A and 1B are cross-sectional views of an integrated circuit (IC) package, according to aspects of the disclosure.

FIGS. 2A-20 illustrate structures at various stages of manufacturing a substrate for an IC package, according to aspects of the disclosure.

FIGS. 3A-3F illustrate structures at various stages of manufacturing a substrate for an IC package, according to aspects of the disclosure.

FIG. 4 illustrates a method for manufacturing a substrate for an IC package, according to aspects of the disclosure.

FIG. 5 illustrates a mobile device, according to aspects of the disclosure.

FIG. 6 illustrates various electronic devices that may incorporate IC devices being put into the IC packages described herein, according to aspects of the disclosure.

In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Aspects of the disclosure are provided in the following description and related drawings directed to various examples provided for illustration purposes. Alternate aspects may be devised without departing from the scope of the disclosure. Additionally, well-known elements of the disclosure will not be described in detail or will be omitted so as not to obscure the relevant details of the disclosure.

The words “exemplary” and/or “example” are used herein to mean “serving as an example, instance, or illustration.” Any aspect described herein as “exemplary” and/or “example” is not necessarily to be construed as preferred or advantageous over other aspects. Likewise, the term “aspects of the disclosure” does not require that all aspects of the disclosure include the discussed feature, advantage, or mode of operation.

In certain described example implementations, instances are identified where various component structures and portions of operations can be taken from known, conventional techniques, and then arranged in accordance with one or more aspects. In such instances, internal details of the known, conventional component structures and/or portions of operations may be omitted to help avoid potential obfuscation of the concepts illustrated in the illustrative aspects disclosed herein.

The terminology used herein is for the purpose of describing particular aspects only and is not intended to be limiting. As used herein, the singular forms “a,” “an,” and “the” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof. Additionally, terms such as approximately, generally, substantially and the like indicate that the examples provided are not intended to be limited to the precise numerical values or geometric shapes and include normal variations due to, manufacturing tolerances and variations, material variations, and other design considerations.

As noted in the foregoing, design restrictions exist for distance between dies and components because of various conventional substrate structures designs as the distance between die to components is fixed to build-up thicknesses. In conventional designs, dies and other components, such as deep trench capacitors (DTC), are mounted on the top and/or bottom surfaces of the substrate. Accordingly, it is difficult to control the distance between dies and components, especially for thick substrates, which are driven by more complex designs that include multiple metal layers in the metallization structures to accommodate complex routing, high density signal connections, power connection and the like.

In the various aspects disclosed, to enhance design flexibility and reduce the distance between dies and components, at least one die or component is embedded in a desired location, which can reduce the distances in comparison to conventional designs.

For example, the substrate can be divided and die(s)/component(s) can be embedded in each layer. In some aspects, the substrate structure can be divided by function. Using the various aspects disclosed, the design efficiency can be enhanced and the distance between die and DTC/components can be reduced based on the various design requirements, such as insertion loss, etc. The divided substrates can be merged using various connection techniques, (e.g., using solder balls, solder paste, copper pillars, hybrid bonding, etc.). Additionally, by having separate substrates that are merged into one hybrid substrate, the various substrates can be individually tested and verified, which can improve overall yield. For example, a defect in one substrate will not impact the other substrates. For example, if one substrate has a defect, e.g., one defective layer, a substitute substrate can be used with the other substrates to form the hybrid substrate. In contrast, in conventional unitary substrate designs a defect in one layer will cause the whole assembly to be discarded.

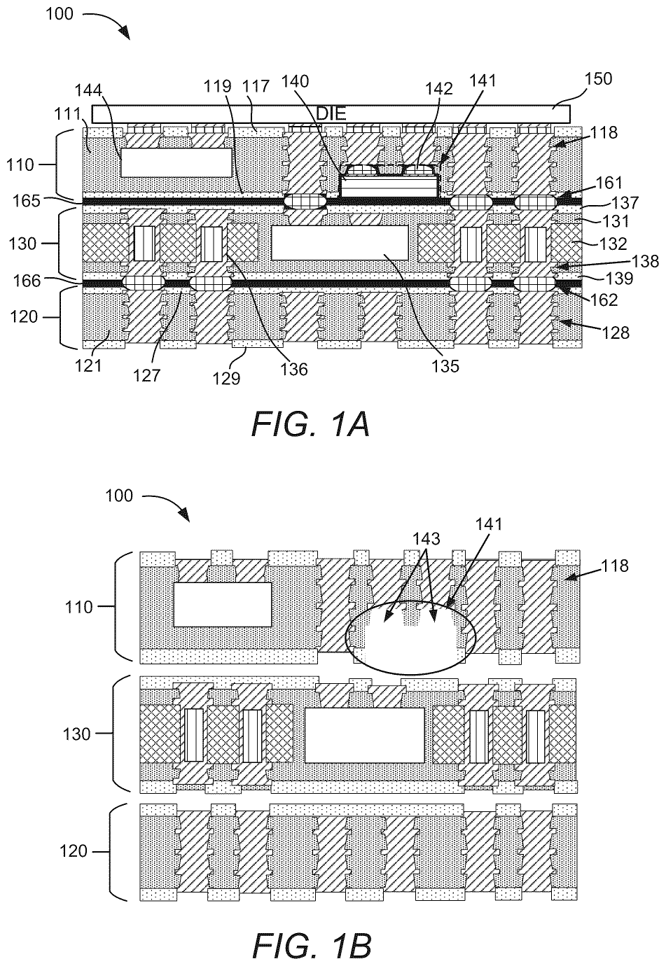

FIG. 1A is a cross-sectional view of an apparatus 100, according to aspects of the disclosure. In some aspects, FIG. 1A is a simplified cross-sectional view of the apparatus 100, and certain details and components of the apparatus 100 may be simplified or omitted in FIG. 1A.

In some aspects, as shown in FIG. 1A, the apparatus 100 may represent partial which may be a portion of an IC package and/or a larger apparatus such as a mobile phone, etc. In an aspect, the apparatus 100 includes a base substrate 130 having a first side and a second side. In some aspects, the base substrate 130 may comprise a core and in other aspects the base substrate 130 may be coreless. A first substrate 110 is disposed on the first side of the base substrate 130. The first substrate 110 has a first embedded component 140 disposed in a cavity 141 (the cavity is filled in the current view) adjacent the first side of the base substrate 130. A second substrate 120 is disposed on the second side of the base substrate 130. A first connection structure 161 (e.g., solder balls, solder paste, copper pillars, etc.) is disposed between the first substrate 110 and the base substrate 130 and is configured to electrically couple the first substrate 110 to the base substrate 130. A second connection structure 162 (e.g., solder balls, solder paste, copper pillars, etc.) is disposed between the second substrate 120 and the base substrate 130 and is configured to electrically couple the second substrate 120 to the base substrate 130.

In some aspects, each of the base substrate 130, the first substrate 110, and the second substrate 120 have a first solder resist layer (solder resist layer 137, solder resist layer 117, solder resist layer 127, respectively) disposed on a first outer surface; and a second solder resist layer (solder resist layer 139, solder resist layer 119, solder resist layer 129, respectively) disposed on a second outer surface.

In some aspects, the base substrate 130 further includes a base metallization structure 138 including a plurality of metal layers and vias coupling the metal layers, which are separated by a base dielectric 131. The first substrate 110 further includes a first metallization structure 118 including a plurality of metal layers and vias coupling the metal layers, which are separated by a first dielectric 111. The second substrate 120 further includes a second metallization structure 128 including a plurality of metal layers and vias coupling the metal layers, which are separated by the second dielectric 121.

In some aspects, the first connection structure 161 is coupled to the first metallization structure 118 and the base metallization structure 138 through openings in adjacent solder resist layers 119 and 137, respectively. The second connection structure 162 is coupled to the second metallization structure 128 and the base metallization structure 138 through openings in adjacent solder resist layers, 127 and 139, respectively. In some aspects, the base substrate 130 is a substrate having a core 132 and the base metallization structure 138 includes at least one plated through hole (PTH) 136 disposed through the core 132 configured to couple portions of the base metallization structure 138 on opposite sides of the core 132. In some aspects, the base substrate 130 further includes a component 135 embedded in the core 132 and enclosed in the base dielectric 131.

In some aspects, the first embedded component 140 comprises a plurality of connectors 142 configured to couple the first embedded component 140 to the first metallization structure 118. In some aspects the first embedded component 140 may be a deep trench capacitor (DTC), an integrated passive device (IPD) or generally any surface-mount device (SMD) or active or passive die. In some aspects the first substrate may include at least one additional embedded component 144. However, it will be appreciated that the various aspects are not limited to the illustrated examples and more embedded components may be included and the location may vary from the example illustrations provided.

In some aspects, the first substrate 110, second substrate 120 and base dielectric 131, the first metallization structure 118, the second metallization structure 128 and the base metallization structure 138 may each be formed at least in part from fiberglass impregnated with resin (prepreg), Ajinomoto build-up film (ABF), a resin coated copper (RCC) build-up film or any similar material. In some aspects, the metal layers and vias of the first metallization structure 118, the second metallization structure 128 and base metallization structure 138 may be any high conductive material, such as, copper (Cu), aluminum (AL), silver (Ag), gold (Au) titanium (Ti), nickel (Ni), tin (Sn), lead (Pb), alloys or combinations thereof.

In some aspects, a first molding compound 165 is disposed between the first substrate 110 and the base substrate 130. The first molding compound at least partially encapsulates the first connection structure 161 and the first embedded component 140. A second molding compound 166 is disposed between the second substrate 120 and the base substrate 130. The second molding compound 166 at least partially encapsulates the second connection structure 162. The first molding compound and the second molding compound may be an epoxy molding compound or any other semiconductor molding compound.

In some aspects, a die 150 may be electrically coupled to the first substrate 110 and be disposed on a surface of the first substrate 110 opposite the base substrate 130. It will be appreciated that various aspects disclosed allow for the first embedded component 140 to be positioned to reduce the distance between the die 150 and the first embedded component 140 and may also be positioned to accommodate signal routing and/or power routing for various designs, which can improve overall performance (e.g., reduced insertion loss, improved decoupling, reduced noise, etc.) of the various designs, as discussed herein. It will be appreciated that one or more dies may be coupled to the first substrate and the various aspects disclosed and claimed are not limited to the illustrated examples.

It will be appreciated that the illustrated configurations and descriptions provided herein are merely to aid in the explanation of the various aspects disclosed herein. Accordingly, the forgoing illustrative examples should not be construed to limit the various aspects disclosed and claimed herein.

FIG. 1B is a cross-sectional view of an apparatus 100, according to aspects of the disclosure. In some aspects, FIG. 1B is a simplified cross-sectional view of the apparatus 100, and certain details and components of the apparatus 100 may be simplified or omitted in FIG. 1B.

In some aspects, as shown in FIG. 1B, the apparatus 100 may be a portion of an IC package and/or a larger apparatus such as a mobile phone, etc. The illustration of FIG. 1B illustrates the various parts before they are merged into the hybrid substrate and before a component is embedded in the first substrate 110. Since many of the elements were previously described in relation to FIG. 1A, a simplified labeling and description will be provided to avoid unnecessary illustration complexity and repetition. As illustrated, the apparatus 100 includes the base substrate 130, the first substrate 110 and the second substrate 120, which each may be fabricated independently. As noted above, this allows for increased yield, since a defect in one of the base substrate 130, the first substrate 110 or the second substrate 120, would not impact the others and would allow for the defective element to be replaced prior to the merger. Additionally, the first substrate 110 has a cavity 141 (the formation of which is discussed below) formed on a side that will be adjacent the first side of the base substrate 130. At this stage of fabrication, a component is not yet embedded in the cavity 141. However, it will be appreciated that the cavity 141 is formed including openings 143 to allow for the first embedded component to be electrically coupled to the first metallizations structure 118, as previously discussed. It will be appreciated that cavity 141 may be formed in any location of the first substrate and further that more than one cavity 141 may be formed to accommodate various designs and provide improved performance, as discussed herein.

In order to fully illustrate aspects of the design of the present disclosure, methods of fabrication are presented. Further, many details in the fabrication process known to those skilled in the art may have been omitted or combined in summary process portions to facilitate an understanding of the various aspects disclosed without a detailed rendition of each detail and/or all possible process variations. Other methods of fabrication are possible, and discussed fabrication methods are presented only to aid understanding of the concepts disclosed herein.

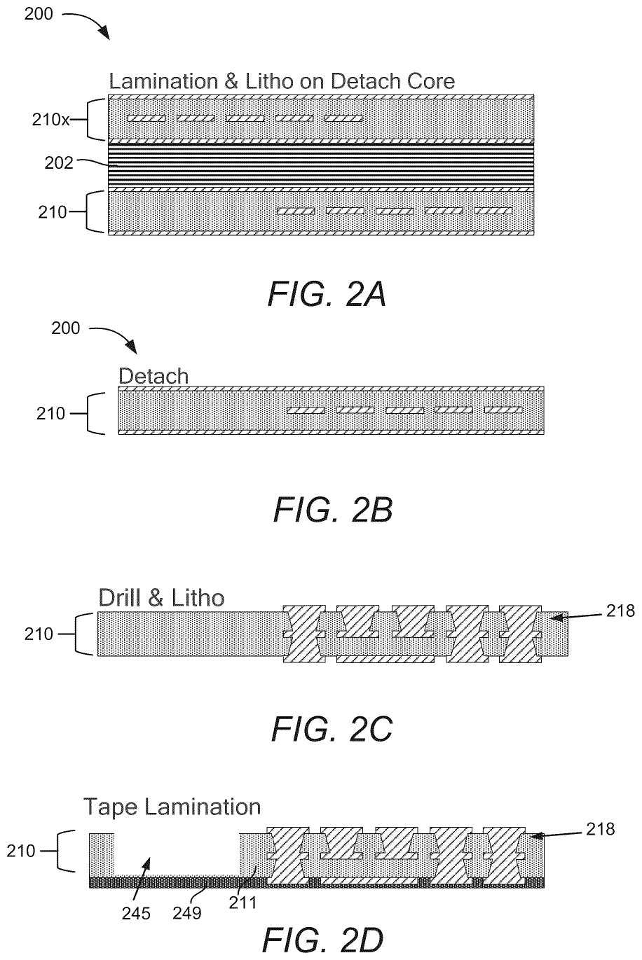

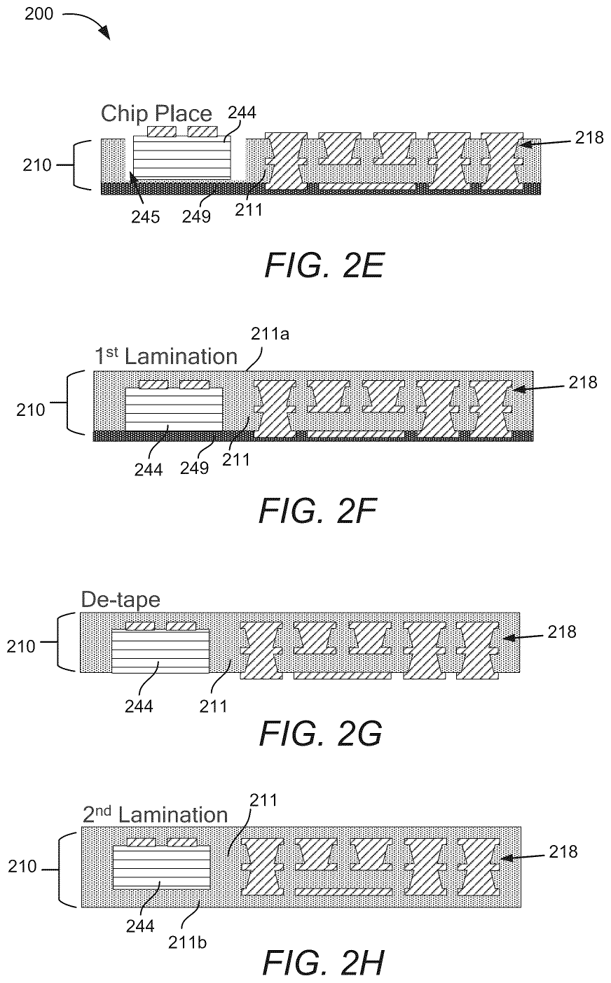

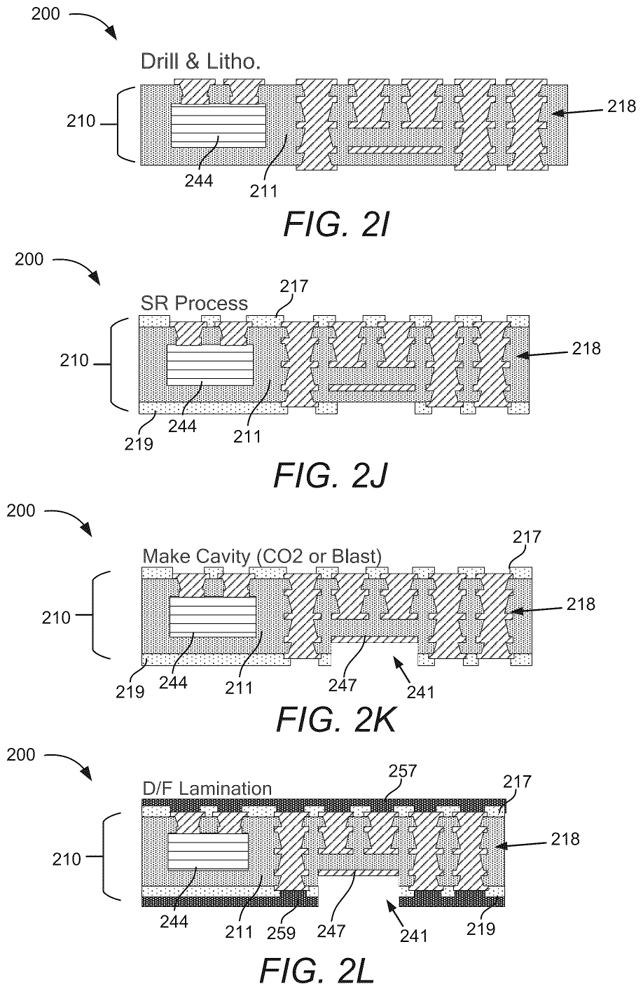

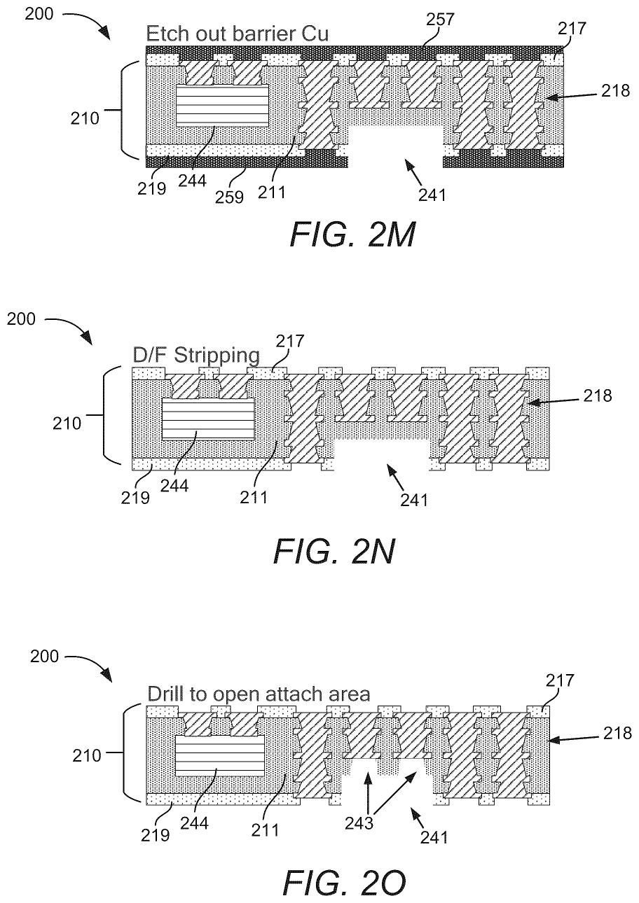

FIGS. 2A-20 illustrate structures at various stages of manufacturing/fabricating an apparatus 200, such as the example apparatus 100 in FIG. 1A as a non-limiting example, according to aspects of the disclosure. Many of the elements illustrated in FIGS. 2A-20 are the same or similar to those of FIG. 1A, and therefore detailed description thereof may be omitted.

As shown in FIG. 2A, the fabrication process for apparatus 200 may begin with a first substrate 210 being formed on a detach core 202 using conventional lamination and lithography techniques. An additional substrate 210x may be formed on opposite side of the detach core 202 from the first substrate 210. In some aspects, the substrate 210x may be configured the same as substrate 210 and in other aspects the substrate 210x may be configured differently.

In FIG. 2B, the fabrication process may continue with the first substrate 210 being detached from the detach core 202 for further processing.

In FIG. 2C, the fabrication process for apparatus 200 may continue with the first substrate 210 being drilled and additional lithographic processes being performed to begin forming the first metallization structure 218.

In FIG. 2D, the fabrication process for apparatus 200 may continue with the first substrate 210 and the first metallization structure 218 being formed, at least in part. At this stage, a tape 249 is laminated to the first substrate 210 to provide support for further processing and a cavity 245 is formed. In some aspects, the cavity may be formed in the first dielectric 211 by laser drilling, laser trenching, sand blasting, etching, or any suitable process known in the art.

In FIG. 2E, the fabrication process for apparatus 200 may continue with the first substrate 210, the first dielectric 211, the first metallization structure 218 and the cavity 245 being formed, at least in part and with the tape 249 applied to the first substrate 210. At this stage, the additional embedded component 244 is placed in the cavity 245 and secured by the tape 249.

In FIG. 2F, the fabrication process for apparatus 200 may continue with the first substrate 210, the first dielectric 211, and the first metallization structure 218 being formed, at least in part. The tape 249 is still attached to the first substrate 210 and the additional embedded component 244 is embedded in the first substrate 210. At this stage, a first dielectric portion 211a is laminated or deposited on a side of the first substrate 210 opposite the tape 249. The first dielectric portion 211a fills in any remaining opening of the cavity 245 (not visible) and covers a top portion of additional embedded component 244 and the metal layers and vias of the first metallization structure 218. In some aspects, the first dielectric portion 211a is the same material as the first dielectric 211 and therefore forms a part of the first dielectric 211 and the combination will be referred to hereafter as the first dielectric 211.

In FIG. 2G, the fabrication process for apparatus 200 may continue with the first substrate 210, the first dielectric 211, and the first metallization structure 218 being formed, at least in part. The additional embedded component 244 is embedded in the first substrate 210. At this stage, the tape is removed from the first substrate.

In FIG. 2H, the fabrication process for apparatus 200 may continue with the first substrate 210, the first dielectric 211, and the first metallization structure 218 being formed, at least in part. The additional embedded component 244 is embedded in the first substrate 210. At this stage, a second dielectric portion 211b is laminated or deposited on a side of the first substrate 210 where the tape was removed. The second dielectric portion 211b covers a bottom portion of additional embedded component 244 and the metal layers and vias of the first metallization structure 218. In some aspects, the second dielectric portion 211b is the same material as the first dielectric 211 and therefore forms a part of the first dielectric 211 and the combination will be referred to hereafter as the first dielectric 211.

In FIG. 2I, the fabrication process for apparatus 200 may continue with the first substrate 210, the first dielectric 211, and the first metallization structure 218 being formed, at least in part. The additional embedded component 244 is embedded in the first substrate 210. At this stage, drilling and lithographic processes are performed to extend the metal elements of the first metallization structure 218 through the additional dielectric layers that were deposited in the previous stages to allow for the metal elements of the first metallization structure 218 to be exposed on both sides of the first substrate 210. Additionally, metal elements of the first metallization structure 218 are formed to allow for contacts of the additional embedded component 244 to be exposed on a top side of the first substrate 210.

In FIG. 2J, the fabrication process for apparatus 200 may continue with the first substrate 210, the first dielectric 211, and the first metallization structure 218 being formed, at least in part. The additional embedded component 244 is embedded in the first substrate 210. At this stage, a top solder resist layer 217 is deposited on the top side of the first substrate 210 and a bottom solder resist layer 219 is deposited on a bottom side of the first substrate 210. The top solder resist layer and the bottom solder resist layer 219 is patterned and etched to form openings to allow for the metal elements of the first metallization structure 218 to be exposed on both sides of the first substrate 210.

In FIG. 2K, the fabrication process for apparatus 200 may continue with the first substrate 210, the first dielectric 211, the first metallization structure 218 and solder resist layers 217 and 219 being formed, at least in part. The additional embedded component 244 is embedded in the first substrate 210. At this stage, a cavity 241 is formed in the first substrate 210. A metal stop 247 is used to set the depth of the cavity 241. In some aspects, the metal stop 247 may be copper and formed as part of the metallization structure 218. The cavity may be formed by laser drilling/ablation/trenching, sand blasting, or any suitable technique for forming a cavity in a substrate.

In FIG. 2L, the fabrication process for apparatus 200 may continue with the first substrate 210, the first dielectric 211, the first metallization structure 218 and solder resist layers 217 and 219 being formed, at least in part. The additional embedded component 244 is embedded in the first substrate 210 and a cavity 241 is formed with a metal stop 247 at the bottom of the cavity 241. At this stage, a top dry film layer 257 is deposited on the top side of the first substrate 210, which covers the entire top surface and a bottom dry film layer 259 is deposited on a bottom side of the first substrate 210, which covers the bottom surface of the first substrate 210, except the cavity 241.

In FIG. 2M, the fabrication process for apparatus 200 may continue with the first substrate 210, the first dielectric 211, the first metallization structure 218, solder resist layers 217 and 219 and dry film layers 257 and 259 being formed, at least in part. The additional embedded component 244 is embedded in the first substrate 210 and a cavity 241 is formed. At this stage, the metal stop 247 (not illustrated) at the bottom of the cavity 241 is removed. The metal stop may be removed by a lithography process including selective etching or any other suitable process.

In FIG. 2N, the fabrication process for apparatus 200 may continue with the first substrate 210, the first dielectric 211, the first metallization structure 218 and solder resist layers 217 and 219 being formed, at least in part. The additional embedded component 244 is embedded in the first substrate 210 and a cavity 241 is formed. At this stage, the top dry film layer and the bottom dry film layer is removed.

In FIG. 2O, the fabrication process for apparatus 200 may continue with the first substrate 210, the first dielectric 211, the first metallization structure 218 and solder resist layers 217 and 219 being formed, at least in part. The additional embedded component 244 is embedded in the first substrate 210 and a cavity 241 is formed. At this stage, the cavity 241 is expanded by forming opening portions 243 to allow for the electrical coupling to the first metallization structure 218. In some aspects, the opening portions 243 may be formed by drilling or any suitable process to remove the dielectric 211 material.

It will be appreciated that additional processing can be performed using known techniques to form and attach additional structures (e.g., second substrate 120, base substrate 130, first embedded component 140, etc.) to first substrate 210 to form a hybrid substrate similar to that illustrated in FIG. 1A. Further, it will be appreciated that the various aspects disclosed are not limited to the specific configurations illustrated in the accompanying figures.

It will be appreciated that the foregoing fabrication process was provided merely as a general illustration of some of the aspects of the disclosure and is not intended to limit the disclosure or accompanying claims. Further, many details in the fabrication process known to those skilled in the art may have been omitted or combined in summary process portions to facilitate an understanding of the various aspects disclosed without a detailed rendition of each detail and/or all possible process variations.

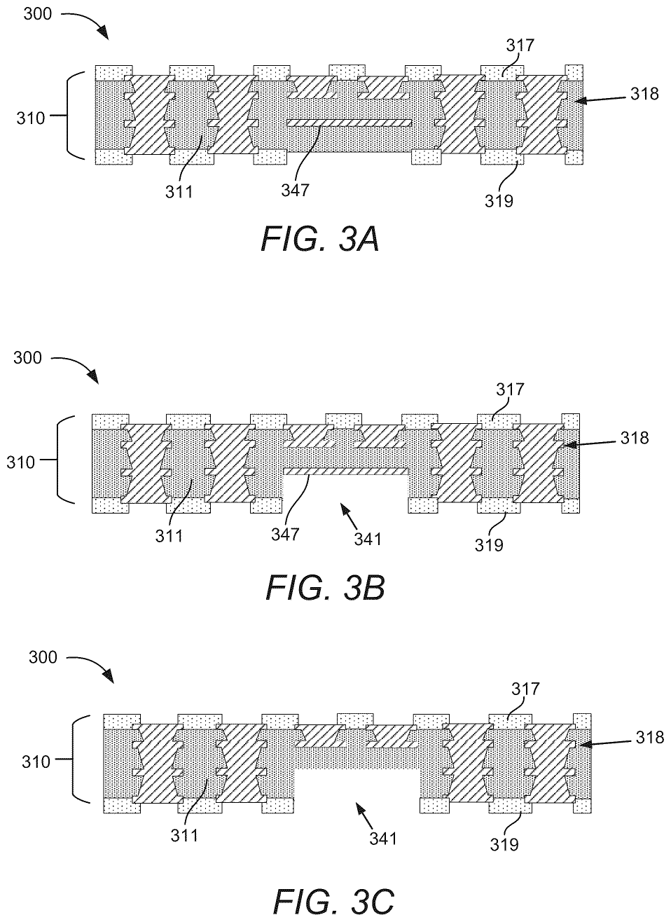

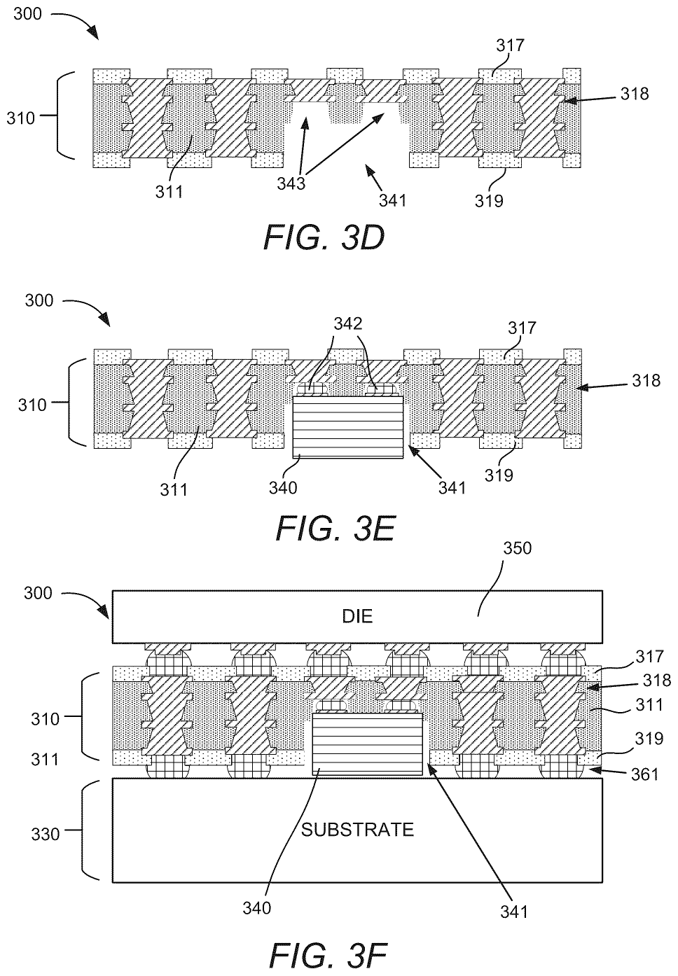

FIGS. 3A-3F illustrate structures at various stages of manufacturing/fabricating an apparatus 300, such as the example apparatus 100 in FIG. 1A as a non-limiting example, according to aspects of the disclosure. Many of the elements illustrated in FIGS. 3A-3F are the same or similar to those of FIG. 1A. Additionally, the process stages are truncated to minimize redundant descriptions. Therefore, detailed description of elements and process stages may be omitted.

As shown in FIG. 3A, the fabrication process for apparatus 300 may begin with a first substrate 310, a first dielectric 311, a first metallization structure 318 and solder resist layers 317 and 319 being formed, at least in part. Additionally, a metal stop 347 is used to set the depth of the cavity to be formed. It will be appreciated that conventional embedded trace substrate (ETS) processing, or any suitable build-up process may be used to form the substrate 310 as illustrated at this stage.

In FIG. 3B, the fabrication process for apparatus 300 may continue with the first substrate 310, the first dielectric 311, the first metallization structure 318, solder resist layers 317 and 319, and metal stop 347 being formed, at least in part. At this stage, a cavity 341 is formed in the first substrate 310. The metal stop 347 is used to set the depth of the cavity 341. In some aspects, the metal stop 347 may be copper and formed as part of the metallization structure 318. The cavity may be formed by laser drilling/ablation/trenching, sand blasting, or any suitable technique for forming a cavity in a substrate.

In FIG. 3C, the fabrication process for apparatus 300 may continue with the first substrate 310, the first dielectric 311, the first metallization structure 318, solder resist layers 317 and 319, and metal stop 347 at the bottom of the cavity 341 being formed, at least in part. At this stage, the metal stop 347 (not illustrated) at the bottom of the cavity 341 is removed. The metal stop may be removed by a lithography process including selective etching or any other suitable process.

In FIG. 3D, the fabrication process for apparatus 300 may continue with the first substrate 310, the first dielectric 311, the first metallization structure 318, solder resist layers 317 and 319, and the cavity 341 being formed, at least in part. At this stage, the cavity 341 is expanded by forming opening portions 343 to allow for electrical coupling to the first metallization structure 318. In some aspects, the opening portions 343 may be formed by drilling or any suitable process to remove the first dielectric 311 material.

In FIG. 3E, the fabrication process for apparatus 300 may continue with the first substrate 310, the first dielectric 311, the first metallization structure 318, solder resist layers 317 and 319, and the cavity 341 being formed, at least in part. At this stage, a first embedded component 340 is attached to the first substrate 310. A plurality of connectors 342 are configured to couple the first embedded component 340 to the first metallization structure 318. For example, solder balls, solder paste or any suitable connector and electrical connection process (e.g., reflow, direct printing, etc.) may be used to couple the first embedded component 340 to the metallization structure 318. In some aspects the first embedded component 340 may be a deep trench capacitor (DTC), an integrated passive device (IPD) or generally any surface-mount device (SMD) or die.

In FIG. 3F, the fabrication process for apparatus 300 may continue with the first substrate 310, the first dielectric 311, the first metallization structure 318, and solder resist layers 317 and 319 being formed, at least in part. The first embedded component 340 is attached to the first substrate 310 in the cavity 341. At this stage, a first connection structure 361 (e.g., solder balls, solder paste, copper pillars, etc.) is formed (e.g., solder reflow process, etc.) between the first substrate 310 and the base substrate 330 to electrically couple the first substrate 310 to the base substrate 330. Additionally, a die 350 is attached to the first substrate 310.

It will be appreciated that additional processing can be performed using known techniques to form and attach additional structures (e.g., second substrate 120, etc.) to first substrate 310 and base substrate 330 to form a hybrid substrate similar to that illustrated in FIG. 1A. In some aspects the base substrate 330 may have a core, such as illustrated in relation to base substrate 130. In other aspects, the base substrate 330 may be a coreless substrate. Further, the various aspects disclosed may include additional substrates that may be used to interface to printed circuit board (PCB) or other external device. Accordingly, it will be appreciated that the various aspects disclosed are not limited to the specific configurations illustrated in the accompanying figures.

It will be appreciated that the foregoing fabrication process was provided merely as a general illustration of some of the aspects of the disclosure and is not intended to limit the disclosure or accompanying claims. Further, many details in the fabrication process known to those skilled in the art may have been omitted or combined in summary process portions to facilitate an understanding of the various aspects disclosed without a detailed rendition of each detail and/or all possible process variations.

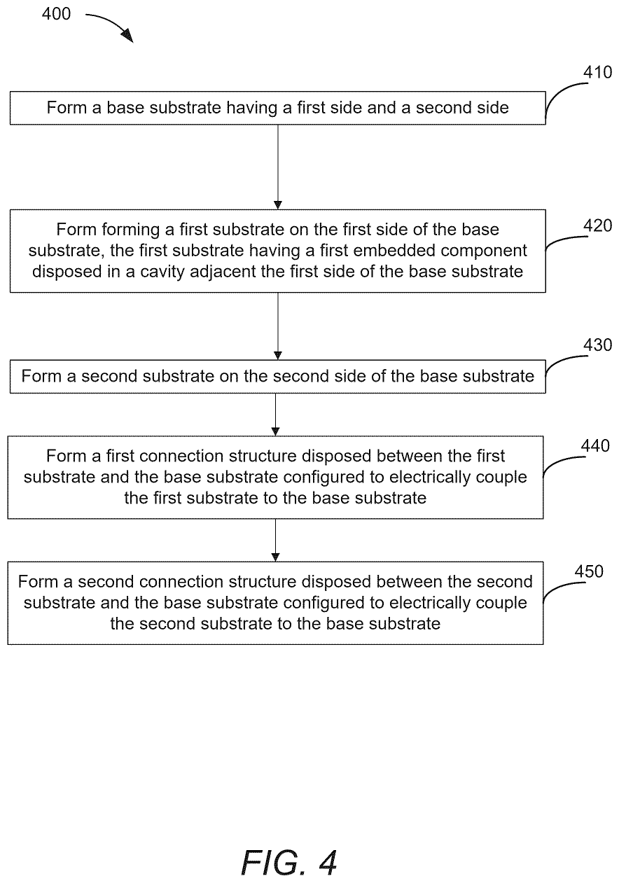

FIG. 4 illustrates a method 400 for manufacturing/fabricating and apparatus with a hybrid substrate with embedded components (such as a substrate for an IC package incorporating the features of any of the example apparatuses 100, 200, or 300), according to aspects of the disclosure. In some aspects, FIGS. 2A-20 and 3A-3F may depict the substrate at different stages of manufacturing according to the method 400. It will be appreciated from the foregoing that there are various methods for fabricating devices including a hybrid substrate with embedded components disclosed herein.

At operation 410, the process includes forming a base substrate having a first side and a second side (e.g., base substrate 130 or 330).

At operation 420, the process includes forming a first substrate on the first side of the base substrate (e.g., base substrate 130 or 330). The first substrate (e.g., first substrate 110, 210, or 310) includes a first embedded component (e.g., first embedded component 140 or 340) disposed in a cavity (e.g., cavity 141, 241, or 341) adjacent the first side of the base substrate (e.g., base substrate 130 or 330).

At operation 430, the process includes forming a second substrate on the second side of the base substrate (e.g., second substrate 120).

At operation 440, the process includes forming a first connection structure (e.g., first connection structure 161 or 361) disposed between the first substrate and the base substrate configured to electrically couple the first substrate to the base substrate (e.g., base substrate 130 or 330).

At operation 450, the process includes forming a second connection structure (e.g., second connection structure 162) disposed between the second substrate and the base substrate configured to electrically couple the second substrate to the base substrate (e.g., base substrate 130 or 330).

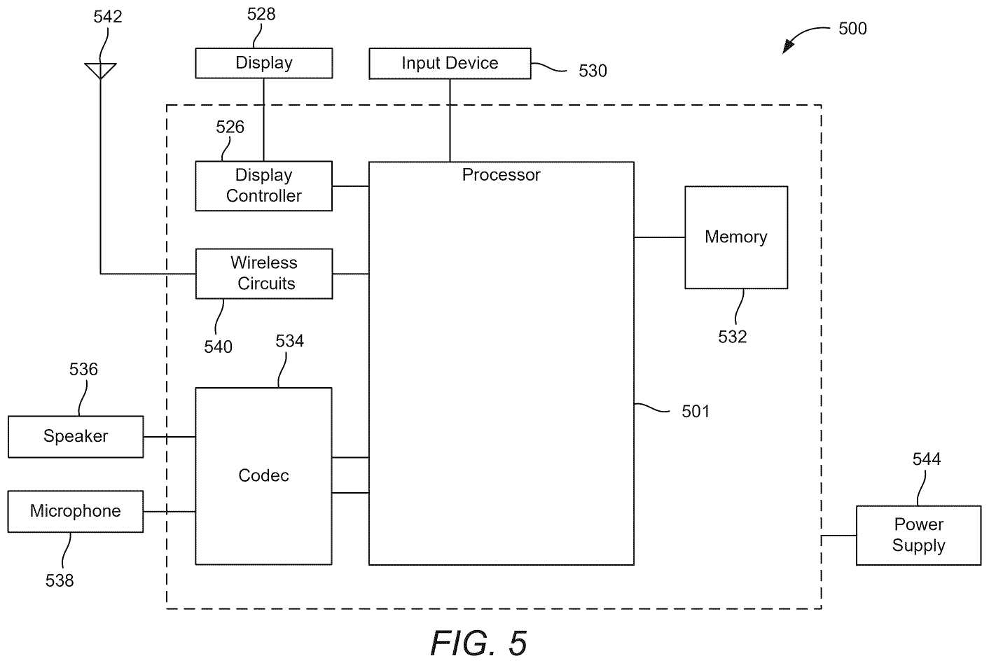

FIG. 5 illustrates a mobile device 500, according to aspects of the disclosure. In some aspects, the mobile device 500 may be implemented by including one or more IC devices including the hybrid substrate with embedded components as disclosed herein.

In some aspects, mobile device 500 may be configured as a wireless communication device. As shown, mobile device 500 includes processor 501. Processor 501 may be communicatively coupled to memory 532 over a link, which may be a die-to-die or chip-to-chip link. Mobile device 500 also includes display 528 and display controller 526, with display controller 526 coupled to processor 501 and to display 528. The mobile device 500 may include input device 530 (e.g., physical, or virtual keyboard), power supply 544 (e.g., battery), speaker 536, microphone 538, and wireless antenna 542. In some aspects, the power supply 544 may directly or indirectly provide the supply voltage for operating some or all of the components of the mobile device 500.

In some aspects, FIG. 5 may include coder/decoder (CODEC) 534 (e.g., an audio and/or voice CODEC) coupled to processor 501; speaker 536 and microphone 538 coupled to CODEC 534; and wireless circuits 540 (which may include a modem, RF circuitry, filters, etc.) coupled to wireless antenna 542 and to processor 501.

In some aspects, one or more of processor 501 (e.g., SoCs, application processor (AP), central processing unit (CPU), digital signal processor (DSP), etc.), display controller 526, memory 532, CODEC 534, and wireless circuits 540 (e.g., baseband interface) including IC devices that are packaged as IC packages and including hybrid substrates with embedded components according to the various aspects described in this disclosure.

It should be noted that although FIG. 5 depicts a mobile device 500, similar architecture may be used to implement an apparatus including, a microprocessor, a server, a set top box, a music player, a video player, an entertainment unit, a navigation device, a personal digital assistant (PDA), a fixed location data unit, a computer, a laptop, a tablet, a communications device, a mobile phone, or other similar devices.

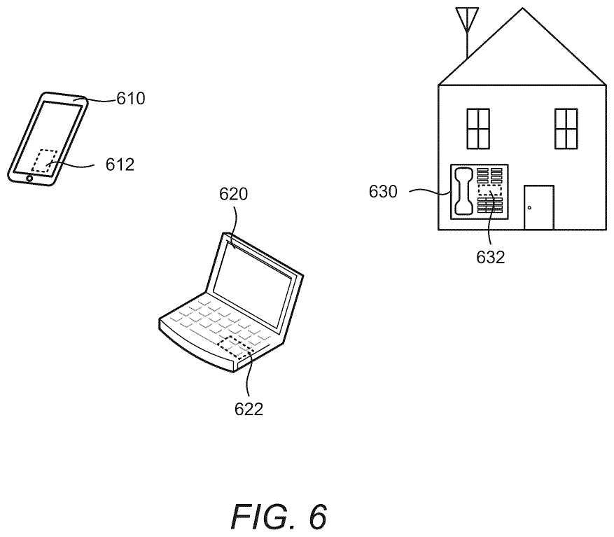

FIG. 6 illustrates various electronic devices 610, 620, and 630 that may incorporate IC devices 612, 622, and 632, which may be packaged as IC packages having hybrid substrates with embedded components as disclosed herein, according to aspects of the disclosure.

For example, a mobile phone device 610, a laptop computer device 620, and a fixed location terminal device 630 may each be considered generally user equipment (UE) and may include one or more IC devices, such as IC devices 612, 622, and 632, and a power supply to provide the supply voltages to power the IC devices. The IC devices 612, 622, and 632 may, for example, correspond to an IC device packaged as an IC package having a hybrid substrate with embedded component manufactured based on the examples described above with reference to FIGS. 2A-30 and 3A-3F.

The devices 610, 620, and 630 illustrated in FIG. 6 are merely non-limiting examples. Other electronic devices may also feature the IC devices including package substrates as described in this disclosure, including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices, servers, routers, electronic devices implemented in automotive vehicles (e.g., autonomous vehicles), an Internet of things (IoT) device, an access point, a base station, or any other device that stores or retrieves data or computer instructions or any combination thereof.

It will be appreciated that various aspects disclosed herein can be described as functional equivalents to the structures, materials and/or devices described and/or recognized by those skilled in the art. For example, in one aspect, an apparatus may comprise a means for performing the various functionalities discussed above. It will be appreciated that the aforementioned aspects are merely provided as examples and the various aspects claimed are not limited to the specific references and/or illustrations cited as examples.

One or more of the components, processes, features, and/or functions illustrated in FIGS. 1A-6 may be rearranged and/or combined into a single component, process, feature, or function or incorporated in several components, processes, or functions. Additional elements, components, processes, and/or functions may also be added without departing from the disclosure. In some implementations, FIGS. 1A-6 and the corresponding description may be used to manufacture, create, provide, and/or produce integrated devices. In some implementations, a device may include a die, an integrated device, a die package, an IC, a device package, an IC package, a wafer, a semiconductor device, a system in package (SiP), a system on chip (SoC), a package on package (POP) device, and the like.

In the detailed description above it can be seen that different features are grouped together in examples. This manner of disclosure should not be understood as an intention that the example clauses have more features than are explicitly mentioned in each clause. Rather, the various aspects of the disclosure may include fewer than all features of an individual example clause disclosed. Therefore, the following clauses should hereby be deemed to be incorporated in the description, wherein each clause by itself can stand as a separate example. Although each dependent clause can refer in the clauses to a specific combination with one of the other clauses, the aspect(s) of that dependent clause are not limited to the specific combination. It will be appreciated that other example clauses can also include a combination of the dependent clause aspect(s) with the subject matter of any other dependent clause or independent clause or a combination of any feature with other dependent and independent clauses. The various aspects disclosed herein expressly include these combinations, unless it is explicitly expressed or can be readily inferred that a specific combination is not intended (e.g., contradictory aspects, such as defining an element as both an electrical insulator and an electrical conductor). Furthermore, it is also intended that aspects of a clause can be included in any other independent clause, even if the clause is not directly dependent on the independent clause.

Implementation examples are described in the following numbered clauses:

Clause 1. An apparatus, comprising: a base substrate having a first side and a second side; a first substrate on the first side of the base substrate, the first substrate having a first embedded component disposed in a cavity adjacent the first side of the base substrate; a second substrate on the second side of the base substrate; a first connection structure disposed between the first substrate and the base substrate configured to electrically couple the first substrate to the base substrate; and a second connection structure disposed between the second substrate and the base substrate configured to electrically couple the second substrate to the base substrate.

Clause 2. The apparatus of clause 1, wherein each of the base substrate, the first substrate, and the second substrate each comprise: a first solder resist layer disposed on a first outer surface; and a second solder resist layer disposed on a second outer surface.

Clause 3. The apparatus of clause 2, wherein: the base substrate further comprises a base metallization structure including a plurality of metal layers and vias coupling the plurality of metal layers, the first substrate further comprises a first metallization structure including a plurality of metal layers and vias coupling the plurality of metal layers, and the second substrate further comprises a second metallization structure including a plurality of metal layers and vias coupling the plurality of metal layers.

Clause 4. The apparatus of clause 3, wherein: the first connection structure is coupled to the first metallization structure and the base metallization structure through openings in adjacent solder resist layers, and the second connection structure is coupled to the second metallization structure and the base metallization structure through openings in adjacent solder resist layers.

Clause 5. The apparatus of clause 4, wherein the base substrate comprises: a substrate having a core.

Clause 6. The apparatus of clause 5, wherein the base metallization structure comprises: at least one plated through hole (PTH) disposed through the core configured to couple portions of the base metallization structure on opposite sides of the core.

Clause 7. The apparatus of clause 6, wherein the base substrate further comprises: a component embedded in the core.

Clause 8. The apparatus of any of clauses 3 to 7, wherein the first embedded component comprises a plurality of connectors configured to couple the first embedded component to the first metallization structure.

Clause 9. The apparatus of any of clauses 3 to 8, wherein the first substrate further comprises: at least one additional embedded component.

Clause 10. The apparatus of any of clauses 3 to 9, wherein the first metallization structure comprises: fiberglass impregnated with resin (prepreg), Ajinomoto build-up film (ABF), or a resin coated copper (RCC) build-up film.

Clause 11. The apparatus of any of clauses 3 to 10, wherein the second substrate further comprises: a component embedded in the second substrate.

Clause 12. The apparatus of any of clauses 3 to 11, wherein the second metallization structure comprises: fiberglass impregnated with resin (prepreg), Ajinomoto build-up film (ABF), or a resin coated copper (RCC) build-up film.

Clause 13. The apparatus of any of clauses 1 to 12, further comprising: a first molding compound disposed between the first substrate and the base substrate, wherein the first molding compound at least partially encapsulates the first connection structure and the first embedded component; and a second molding compound disposed between the second substrate and the base substrate, wherein the second molding compound at least partially encapsulates the second connection structure.

Clause 14. The apparatus of any of clauses 1 to 13, further comprising: a die electrically coupled to the first substrate and disposed on a surface of the first substrate opposite the base substrate.

Clause 15. The apparatus of any of clauses 1 to 14, wherein the apparatus comprises at least one of: a music player, a video player, an entertainment unit; a navigation device, a communications device, a mobile device, a mobile phone, a smartphone, a personal digital assistant, a fixed location terminal, a tablet computer, a computer, a wearable device, a laptop computer, a server, an internet of things (IoT) device, or a device in an automotive vehicle.

Clause 16. A method of manufacturing an apparatus, the method comprising: forming a base substrate having a first side and a second side; forming a first substrate on the first side of the base substrate, the first substrate having a first embedded component disposed in a cavity adjacent the first side of the base substrate; forming a second substrate on the second side of the base substrate; forming a first connection structure disposed between the first substrate and the base substrate configured to electrically couple the first substrate to the base substrate; and forming a second connection structure disposed between the second substrate and the base substrate configured to electrically couple the second substrate to the base substrate.

Clause 17. The method of clause 16, wherein each of the base substrate, the first substrate, and the second substrate each comprise: a first solder resist layer disposed on a first outer surface; and a second solder resist layer disposed on a second outer surface.

Clause 18. The method of clause 17, wherein: the base substrate further comprises a base metallization structure including a plurality of metal layers and vias coupling the plurality of metal layers, the first substrate further comprises a first metallization structure including a plurality of metal layers and vias coupling the plurality of metal layers, and the second substrate further comprises a second metallization structure including a plurality of metal layers and vias coupling the plurality of metal layers.

Clause 19. The method of clause 18, wherein: the first connection structure is coupled to the first metallization structure and the base metallization structure through openings in adjacent solder resist layers, and the second connection structure is coupled to the second metallization structure and the base metallization structure through openings in adjacent solder resist layers.

Clause 20. The method of clause 19, wherein the base substrate comprises: a substrate having a core.

Clause 21. The method of clause 20, wherein the base metallization structure comprises: at least one plated through hole (PTH) disposed through the core configured to couple portions of the base metallization structure on opposite sides of the core.

Clause 22. The method of clause 21, wherein forming the base substrate further comprises: embedding a component in the core.

Clause 23. The method of any of clauses 18 to 22, wherein the first embedded component comprises a plurality of connectors configured to couple the first embedded component to the first metallization structure.

Clause 24. The method of any of clauses 18 to 23, wherein forming the first substrate further comprises: embedding at least one additional embedded component.

Clause 25. The method of any of clauses 18 to 24, wherein the first metallization structure comprises: fiberglass impregnated with resin (prepreg), Ajinomoto build-up film (ABF), or a resin coated copper (RCC) build-up film.

Clause 26. The method of any of clauses 18 to 25, wherein forming the second substrate further comprises: embedding a component in the second substrate.

Clause 27. The method of any of clauses 18 to 26, wherein the second metallization structure comprises: fiberglass impregnated with resin (prepreg), Ajinomoto build-up film (ABF), or a resin coated copper (RCC) build-up film.

Clause 28. The method of any of clauses 16 to 27, further comprising: disposing a first molding compound between the first substrate and the base substrate, wherein the first molding compound at least partially encapsulates the first connection structure and the first embedded component; and disposing a second molding compound between the second substrate and the base substrate, wherein the second molding compound at least partially encapsulates the second connection structure.

Clause 29. The method of any of clauses 16 to 28, further comprising: electrically coupling a die to the first substrate, wherein the die is disposed on a surface of the first substrate opposite the base substrate.

Clause 30. The method of any of clauses 16 to 29, wherein the apparatus comprises at least one of: a music player, a video player, an entertainment unit; a navigation device, a communications device, a mobile device, a mobile phone, a smartphone, a personal digital assistant, a fixed location terminal, a tablet computer, a computer, a wearable device, a laptop computer, a server, an internet of things (IoT) device, or a device in an automotive vehicle.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithm steps described in connection with the aspects disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a general-purpose processor, a DSP, an ASIC, an FPGA, or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The methods, sequences and/or algorithms described in connection with the aspects disclosed herein may be embodied directly in hardware, in a software module executed by a processor, or in a combination of the two. A software module may reside in random access memory (RAM), flash memory, read-only memory (ROM), erasable programmable ROM (EPROM), electrically erasable programmable ROM (EEPROM), registers, hard disk, a removable disk, a CD-ROM, or any other form of storage medium known in the art. An example storage medium is coupled to the processor such that the processor can read information from, and write information to, the storage medium. In the alternative, the storage medium may be integral to the processor. The processor and the storage medium may reside in an ASIC. The ASIC may reside in a user terminal (e.g., UE). In the alternative, the processor and the storage medium may reside as discrete components in a user terminal.

In one or more example aspects, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

Furthermore, as used herein, the terms “set,” “group,” and the like are intended to include one or more of the stated elements. Also, as used herein, the terms “has,” “have,” “having,” “comprises,” “comprising,” “includes,” “including,” and the like does not preclude the presence of one or more additional elements (e.g., an element “having” A may also have B). Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”) or the alternatives are mutually exclusive (e.g., “one or more” should not be interpreted as “one and more”). Furthermore, although components, functions, actions, and instructions may be described or claimed in the singular, the plural is contemplated unless limitation to the singular is explicitly stated. Accordingly, as used herein, the articles “a,” “an,” “the,” and “said” are intended to include one or more of the stated elements. Additionally, as used herein, the terms “at least one” and “one or more” encompass “one” component, function, action, or instruction performing or capable of performing a described or claimed functionality and also “two or more” components, functions, actions, or instructions performing or capable of performing a described or claimed functionality in combination.

While the foregoing disclosure shows illustrative aspects of the disclosure, it should be noted that various changes and modifications could be made herein without departing from the scope of the disclosure as defined by the appended claims. For example, the functions, steps and/or actions of the method claims in accordance with the aspects of the disclosure described herein need not be performed in any particular order. Further, no component, function, action, or instruction described or claimed herein should be construed as critical or essential unless explicitly described as such.

What is claimed is:

1. An apparatus, comprising:
a base substrate having a first side and a second side;
a first substrate on the first side of the base substrate, the first substrate having a first embedded component disposed in a cavity adjacent the first side of the base substrate;
a second substrate on the second side of the base substrate;
a first connection structure disposed between the first substrate and the base substrate configured to electrically couple the first substrate to the base substrate; and
a second connection structure disposed between the second substrate and the base substrate configured to electrically couple the second substrate to the base substrate.

2. The apparatus of claim 1, wherein each of the base substrate, the first substrate, and the second substrate each comprise:
a first solder resist layer disposed on a first outer surface; and
a second solder resist layer disposed on a second outer surface.

3. The apparatus of claim 2, wherein:
the base substrate further comprises a base metallization structure including a plurality of metal layers and vias coupling the plurality of metal layers,
the first substrate further comprises a first metallization structure including a plurality of metal layers and vias coupling the plurality of metal layers, and
the second substrate further comprises a second metallization structure including a plurality of metal layers and vias coupling the plurality of metal layers.

4. The apparatus of claim 3, wherein:
the first connection structure is coupled to the first metallization structure and the base metallization structure through openings in adjacent solder resist layers, and
the second connection structure is coupled to the second metallization structure and the base metallization structure through openings in adjacent solder resist layers.

5. The apparatus of claim 4, wherein the base substrate comprises:
a substrate having a core.

6. The apparatus of claim 5, wherein the base metallization structure comprises:
at least one plated through hole (PTH) disposed through the core configured to couple portions of the base metallization structure on opposite sides of the core.

7. The apparatus of claim 6, wherein the base substrate further comprises:
a component embedded in the core.

8. The apparatus of claim 3, wherein the first embedded component comprises a plurality of connectors configured to couple the first embedded component to the first metallization structure.

9. The apparatus of claim 3, wherein the first substrate further comprises:
at least one additional embedded component.

10. The apparatus of claim 3, wherein the first metallization structure comprises:
fiberglass impregnated with resin (prepreg), Ajinomoto build-up film (ABF), or a resin coated copper (RCC) build-up film.

11. The apparatus of claim 3, wherein the second substrate further comprises:
a component embedded in the second substrate.

12. The apparatus of claim 3, wherein the second metallization structure comprises:
fiberglass impregnated with resin (prepreg), Ajinomoto build-up film (ABF), or a resin coated copper (RCC) build-up film.

13. The apparatus of claim 1, further comprising:
a first molding compound disposed between the first substrate and the base substrate, wherein the first molding compound at least partially encapsulates the first connection structure and the first embedded component; and
a second molding compound disposed between the second substrate and the base substrate, wherein the second molding compound at least partially encapsulates the second connection structure.

14. The apparatus of claim 1, further comprising:
a die electrically coupled to the first substrate and disposed on a surface of the first substrate opposite the base substrate.

15. The apparatus of claim 1, wherein the apparatus comprises at least one of: a music player, a video player, an entertainment unit; a navigation device, a communications device, a mobile device, a mobile phone, a smartphone, a personal digital assistant, a fixed location terminal, a tablet computer, a computer, a wearable device, a laptop computer, a server, an internet of things (IoT) device, or a device in an automotive vehicle.

16. A method of manufacturing an apparatus, the method comprising:
forming a base substrate having a first side and a second side;
forming a first substrate on the first side of the base substrate, the first substrate having a first embedded component disposed in a cavity adjacent the first side of the base substrate;
forming a second substrate on the second side of the base substrate;
forming a first connection structure disposed between the first substrate and the base substrate configured to electrically couple the first substrate to the base substrate; and
forming a second connection structure disposed between the second substrate and the base substrate configured to electrically couple the second substrate to the base substrate.

17. The method of claim 16, wherein each of the base substrate, the first substrate, and the second substrate each comprise:
a first solder resist layer disposed on a first outer surface; and
a second solder resist layer disposed on a second outer surface.

18. The method of claim 17, wherein:
the base substrate further comprises a base metallization structure including a plurality of metal layers and vias coupling the plurality of metal layers,
the first substrate further comprises a first metallization structure including a plurality of metal layers and vias coupling the plurality of metal layers, and
the second substrate further comprises a second metallization structure including a plurality of metal layers and vias coupling the plurality of metal layers.

19. The method of claim 18, further comprising:
coupling the first connection structure to the first metallization structure and the base metallization structure through openings in adjacent solder resist layers, and
coupling the second connection structure to the second metallization structure and the base metallization structure through openings in adjacent solder resist layers.

20. The method of claim 19, wherein forming the base substrate further comprises:
forming at least one plated through hole (PTH) disposed through a core configured to couple portions of the base metallization structure on opposite sides of the core; and
embedding a component in the core.
